(19) United States
(12) Patent Application Publication
(10) Pub. No.: US 2026/0041006 A1
(43) Pub. Date: Feb. 5, 2026

(54) SEMICONDUCTOR PACKAGE

(71) Applicant: Samsung Electronics Co., Ltd., Suwon-si (KR)

(72) Inventors: Jaechul Kim, Suwon-si (KR); Boseok Kwon, Suwon-si (KR); Taeduk Nam, Suwon-si (KR); Sungkyu Park, Suwon-si (KR); Kwangyong Lee, Suwon-si (KR); Sangjin Lee, Suwon-si (KR); Jungsik Lee, Suwon-si (KR)

(21) Appl. No.: 19/278,303

(22) Filed: Jul. 23, 2025

(30) Foreign Application Priority Data
Aug. 2, 2024 (KR) 10-2024-0103271

(51) Int. Cl. H01L 23/00; H01L 21/56; H01L 23/31; H01L 25/065; H01L 25/18; H10B 80/00; H10D 80/30

(52) U.S. Cl. CPC H01L 24/32; H01L 24/16; H01L 24/29; H01L 24/48; H01L 24/73; H01L 25/0652; H01L 25/18; H01L 21/56; H01L 23/3121; H01L 24/30; H01L 2224/16148; H01L 2224/16227; H01L 2224/16238; H01L 2224/29017; H01L 2224/29019; H01L 2224/3003; H01L 2224/32145; H01L 2224/32225; H01L 2224/48225; H01L 2224/73204; H01L 2224/73215; H01L 2224/73253; H01L 2924/1431; H10B 80/00; H10D 80/30

(57) ABSTRACT

A semiconductor package includes: a package substrate, a first chip on the package substrate, a second chip on the package substrate and spaced apart from the first chip in a horizontal direction, a third chip having a film adhesive layer attached to a lower surface thereof, and attached to the first chip and the second chip, a first fillet adhesive layer surrounding a side surface of the first chip and in contact with a portion of the lower surface of the third chip, and a second fillet adhesive layer between the second chip and the third chip. A vertical level of an upper surface of the first chip is higher than a vertical level of an upper surface of the second chip, and the second fillet adhesive layer protrudes from the upper surface of the second chip in the horizontal direction.

### CROSS-REFERENCE TO RELATED APPLICATION

This application is based on and claims priority under 35 U.S.C. § 119 to Korean Patent Application No. 10-2024-0103271, filed on Aug. 2, 2024, in the Korean Intellectual Property Office, the disclosure of which is incorporated by reference herein in its entirety.

### BACKGROUND

The size and weight of electronic components mounted in electronic products have been reduced as the demand for portable devices rapidly increases in electronics product market. Small and light-weighted electronic semiconductor packages face the challenge of processing high-capacity data with reduced defects while still having a small volume.

In addition, semiconductor packages having a plurality of semiconductor chips stacked in the vertical direction have been developed to reduce the size of the semiconductor package. Maintaining structural reliability of semiconductor packages, even when semiconductor chips are stacked in the vertical direction, is an on-going challenge.

### SUMMARY

In a first general aspect, a semiconductor package includes: a package substrate, a first chip on the package substrate, a second chip on the package substrate and spaced apart from the first chip in a horizontal direction, a third chip having a film adhesive layer attached to a lower surface thereof, and attached onto the first chip and the second chip, a first fillet adhesive layer surrounding a side surface of the first chip and in contact with a portion of the lower surface of the third chip, and a second fillet adhesive layer between the second chip and the third chip, wherein a vertical level of an upper surface of the first chip is higher than a vertical level of an upper surface of the second chip, and the second fillet adhesive layer protrudes from the upper surface of the second chip in the horizontal direction.

In a second general aspect, a semiconductor package includes: a package substrate, a first chip on the package substrate, a second chip on the package substrate and spaced apart from the first chip in a horizontal direction, a third chip having a film adhesive layer attached to a lower surface thereof, and attached onto the first chip and the second chip, a first fillet adhesive layer between the first chip and the third chip, and a second fillet adhesive layer between the second chip and the third chip, wherein the third chip is disposed on the first chip and the second chip in a state of being inclined toward the second chip, a vertical level of an upper surface of the first chip is higher than a vertical level of an upper surface of the second chip, the first fillet adhesive layer protrudes from the upper surface of the first chip in the horizontal direction, and the second fillet adhesive layer protrudes from the upper surface of the second chip in the horizontal direction.

In a third general aspect, a semiconductor package including a package substrate includes: an external connection terminal connected to a lower pad formed on a lower surface thereof, a first chip on an upper surface of the package substrate, a second chip on the upper surface of the package substrate and spaced apart from the first chip in a horizontal direction, a third chip having a film adhesive layer attached to a lower surface thereof, and disposed on the first chip and the second chip, a first fillet adhesive layer surrounding a side surface of the first chip, in contact with a portion of the lower surface of the third chip, and formed by hardening a liquid adhesive, a second fillet adhesive layer between the second chip and the third chip and formed by hardening a liquid adhesive, and a molding member on the package substrate and surrounding the first chip, the second chip, and the third chip, wherein the film adhesive layer has a flat shape extending in the horizontal direction, a vertical level of an upper surface of the first chip is higher than a vertical level of an upper surface of the second chip, the third chip is attached onto the first chip and the second chip while a longitudinal direction of the third chip is substantially perpendicular to a height direction of each of the first chip and the second chip, the first fillet adhesive layer is not between the first chip and the third chip, the second fillet adhesive layer protrudes from the upper surface of the second chip in the horizontal direction, and the molding member is not between the first chip and the third chip and between the second chip and the third chip.

In some implementations, the disclosed semiconductor package is capable of maintaining reliability while efficiently arranging semiconductor chips in a limited space.

In addition, the problems to be solved by the technical idea of the inventive concept are not limited to the problem mentioned above, and other problems could be clearly understood by those of ordinary skill in the art from the description below.

### BRIEF DESCRIPTION OF THE DRAWINGS

FIG. 1 is a cross-sectional view schematically illustrating an example of a semiconductor package.

FIG. 2 is a cross-sectional view schematically illustrating another example of a semiconductor package.

FIG. 3 is a cross-sectional view schematically illustrating another example of a semiconductor package.

FIG. 4 is a cross-sectional view schematically illustrating another example of a semiconductor package.

FIG. 5 is a cross-sectional view schematically illustrating another example of a semiconductor package.

FIG. 6 is a cross-sectional view schematically illustrating another example of a semiconductor package.

FIG. 7 is a cross-sectional view schematically illustrating another example of a semiconductor package.

FIG. 8 is a cross-sectional view schematically illustrating another example of a semiconductor package.

FIG. 9 is a cross-sectional view schematically illustrating another example of a semiconductor package. and

FIGS. 10 to 14 are cross-sectional views of a method of manufacturing the semiconductor package of FIG. 1.

Like reference numerals in the drawings denote like elements, and thus their repetitive description will be omitted.

### DETAILED DESCRIPTION

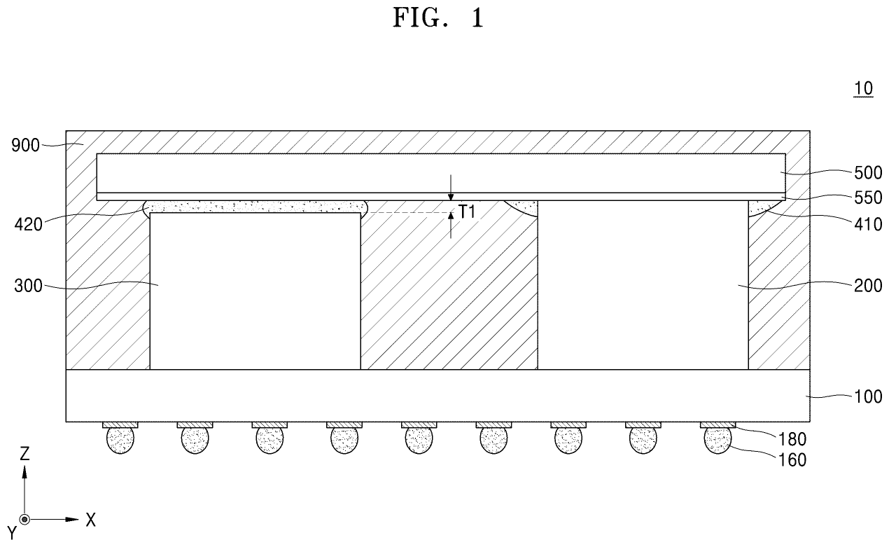

FIG. 1 is a cross-sectional view schematically illustrating an example of a semiconductor package 10.

Referring to FIG. 1, the semiconductor package 10 includes a package substrate 100, a first chip 200, a second chip 300, a third chip 500, a first fillet adhesive layer 410, a second fillet adhesive layer 420, a film adhesive layer 550, and a molding member 900. The package substrate 100 is a substrate on which the first chip 200 and the second chip 300 are mounted and may be beneath the first chip 200 and the second chip 300.

In the drawings below, an X-axis direction and a Y-axis direction indicate directions parallel to the surface of the package substrate 100, and it may be understood that the X-axis direction is perpendicular to the Y-axis direction. A Z-axis direction may indicate a direction perpendicular to the upper surface or the lower surface of the package substrate 100, e.g., a direction perpendicular to an X-Y plane. In addition, in the drawings below, a first horizontal direction, a second horizontal direction, and the vertical direction may be understood as follows. The first horizontal direction may be understood as the X-axis direction, the second horizontal direction may be understood as the Y-axis direction, and the vertical direction may be understood as the Z-axis direction.

In some implementations, the package substrate 100 may be a printed circuit board (PCB) including therein a wiring pattern and an insulating layer surrounding the wiring pattern. Herein, the wiring pattern of the package substrate 100 may include copper (Cu), nickel (Ni), stainless steel, or beryllium copper, and the insulating layer may include at least one material selected from among a phenol resin, an epoxy resin, and polyimide. The insulating layer may include at least one material selected from among flame retardant 4 (FR-4), tetrafunctional epoxy, polyphenylene ether, epoxy/polyphenylene oxide, bismaleimide triazine (BT), Thermount, cyanate ester, polyimide, and liquid crystal polymer.

In some implementations, the package substrate 100 may be a substrate formed by a redistribution process. In this case, the package substrate 100 may include therein a redistribution pattern and a redistribution insulating layer surrounding the redistribution pattern. The redistribution pattern may include a metal, such as Cu, aluminum (Al), tungsten (W), titanium (Ti), tantalum (Ta), indium (In), molybdenum (Mo), manganese (Mn), cobalt (Co), tin (Sn), Ni, magnesium (Mg), rhenium (Re), beryllium (Be), gallium (Ga), or ruthenium (Ru), or an alloy of the metal but is not limited thereto. In some implementations, the redistribution pattern may be formed by stacking a metal or an alloy of the metal on a seed layer including Cu, Ti, titanium nitride, or TiW. The redistribution insulating layer may be formed of photo imageable dielectric (PID) or photosensitive polyimide (PSPI).

An external connection terminal 160 may be on the lower surface of the package substrate 100 and electrically connected to the package substrate 100 via a lower pad 180 formed on the lower surface of the package substrate 100. Particularly, the external connection terminal 160 may be electrically connected to wirings, formed in the package substrate 100, via the lower pad 180 attached to the lower surface of the package substrate 100. Because the external connection terminal 160 is under the package substrate 100, the upper surface of the external connection terminal 160 may be in physical contact with the lower pad 180 attached to the lower surface of the package substrate 100. The external connection terminal 160 may be electrically connected to an external device, for example, a motherboard, a PCB, or the like. Because the external connection terminal 160 is between the external device and the package substrate 100, the lower surface of the external connection terminal 160 may be physically connected to the external device.

The external connection terminal 160 may be formed as a solder ball. However, in some implementations, the external connection terminal 160 may have a structure including a pillar and solder. The external connection terminal 160 may include at least one of Cu, silver (Ag), gold (Au), and Sb.

The first chip 200 may be on the upper surface of the package substrate 100. In some implementations, the first chip 200 may be a semiconductor chip electrically connected to the package substrate 100 or a dummy chip not electrically connected, e.g. electrically insulated from, to the package substrate 100. When the first chip 200 is a semiconductor chip, the first chip 200 may be a memory chip or a logic chip. The memory chip may be, for example, a volatile memory chip, such as dynamic random access memory (DRAM) or static random access memory (SRAM), or a nonvolatile memory chip, such as phase-change random access memory (PRAM), magnetoresistive random access memory (MRAM), ferroelectric random access memory (FeRAM), or resistive random access memory (RRAM). In addition, in some implementations, the memory chip may be a high bandwidth memory (HBM) package in which a plurality of memory chips are stacked in the vertical direction Z, or a wire bonding memory package. In addition, the logic chip may be, for example, a microprocessor, such as a central processing unit (CPU), a graphics processing unit (GPU), or an application processor (AP), an analog device, or a digital signal processor.

When the first chip 200 is a dummy chip, the dummy chip may be a chip used for testing and correction, mechanical stability, heat management, or the like. For example, the dummy chip may be a heat management dummy chip for dispersing heat inside the semiconductor package 10, a mechanical stability dummy chip for improving the mechanical stability of the semiconductor package 10, a test dummy chip for testing and correction, or a simulation signal processing dummy chip for simulating signal processing.

The second chip 300 may be on the package substrate 100 and spaced apart from the first chip 200. In some implementations, the second chip 300 may be a semiconductor chip electrically connected to the package substrate 100 or a dummy chip not electrically connected to the package substrate 100. When the second chip 300 is a semiconductor chip, the second chip 300 may be a memory chip or a logic chip. In addition, when the second chip 300 is a dummy chip, the dummy chip may be a chip used for test and correction, mechanical stability, heat management, or the like.

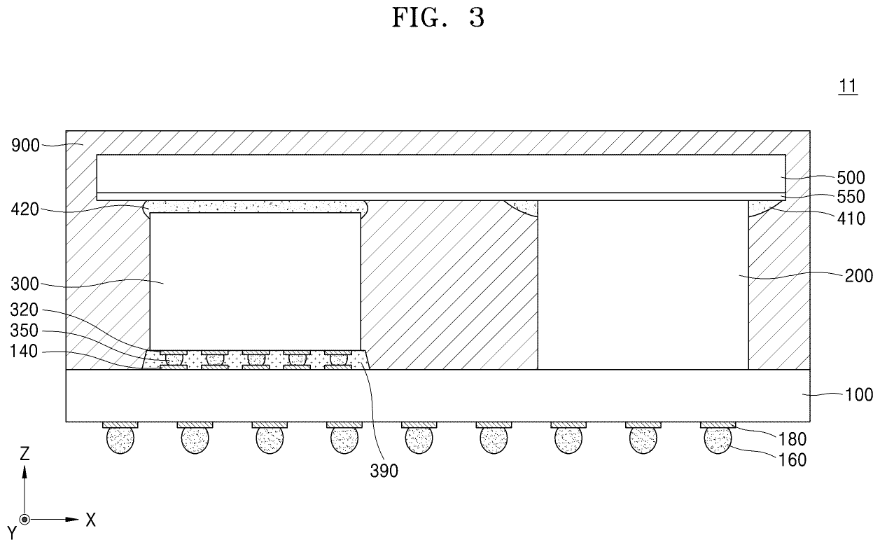

Examples of the first chip 200 and the second chip 300 are described in detail with reference to FIGS. 3 to 9.

In some implementations, the vertical level of the upper surface of the first chip 200 may be higher than the vertical level of the upper surface of the second chip 300. As an example of a case where the vertical level of the upper surface of the first chip 200 is higher than the vertical level of the upper surface of the second chip 300, there may be a case where the height of the first chip 200 in the vertical direction Z may be greater than the height of the second chip 300 in the vertical direction Z. In addition, even when the height of the first chip 200 in the vertical direction Z is substantially less than or equal to the height of the second chip 300 in the vertical direction Z, if a step is formed on the upper surface of the package substrate 100 such that the vertical level of the upper surface of the package substrate 100 on which the first chip 200 is mounted is higher than the vertical level of the upper surface of the package substrate 100 on which the second chip 300 is mounted, the vertical level of the upper surface of the first chip 200 may be higher than the vertical level of the upper surface of the second chip 300. A height difference T1 between the upper surface of the first chip 200 and the upper surface of the second chip 300 may be within a range of 10 μm to 100 μm.

The third chip 500 may be on the first chip 200 and the second chip 300. Particularly, the third chip 500 may be attached onto the first chip 200 and the second chip 300. In some implementations, the third chip 500 may be attached onto the first chip 200 and the second chip 300 in a horizontal orientation. In other words, the third chip 500 may be attached onto the first chip 200 and the second chip 300 while the longitudinal direction of the third chip 500 is perpendicular to the height direction of each of the first chip 200 and the second chip 300. In this case, the third chip 500 may be attached onto the first chip 200 and the second chip 300 through the first fillet adhesive layer 410, the second fillet adhesive layer 420, and the film adhesive layer 550.

The first fillet adhesive layer 410 may be coated in a liquid phase on the upper surface of the first chip 200, and the second fillet adhesive layer 420 may be coated in the liquid phase on the upper surface of the second chip 300. The first fillet adhesive layer 410 and the second fillet adhesive layer 420 may include substantially the same material. In some implementations, the first fillet adhesive layer 410 and the second fillet adhesive layer 420 may include a liquid adhesive. For example, the first fillet adhesive layer 410 and the second fillet adhesive layer 420 may include a silicon-based liquid adhesive or an epoxy-based liquid adhesive. However, the material of the first fillet adhesive layer 410 and the second fillet adhesive layer 420 is not limited thereto. In addition, in the specification, terms such as “liquid phase,” “liquid adhesive,” describing the first fillet adhesive layer 410 and the second fillet adhesive layer 420 refer to a phase before the first fillet adhesive layer 410 and the second fillet adhesive layer 420 are hardened, e.g., the solid phase. In the solid phase, the third chip 500 is completely attached to the first chip 200 and the second chip 300, the first fillet adhesive layer 410 and the second fillet adhesive layer 420 may be hardened.

The first fillet adhesive layer 410 may be provided onto the upper surface of the first chip 200 before the third chip 500 is attached onto the first chip 200. In a process of attaching the third chip 500 onto the upper surface of the first chip 200, the first fillet adhesive layer 410 may protrude from the upper surface of the first chip 200 in a horizontal direction X and/or Y. The first fillet adhesive layer 410 provided between the third chip 500 and the first chip 200 may protrude from the upper surface of the first chip 200 in the horizontal direction X and/or Y by pressure applied from the third chip 500 and the first chip 200 in the vertical direction Z. That is, the first fillet adhesive layer 410 may protrude from the first chip 200 in the horizontal direction X and/or Y.

In some implementations, the first fillet adhesive layer 410 may not remain between the first chip 200 and the third chip 500. That is, the first fillet adhesive layer 410 may not be interposed between the first chip 200 and the third chip 500. In other words, the interface between the first chip 200 and the third chip 500 is free of the first fillet adhesive layer 410. As shown in FIG. 1, for example, an upper surface of the first fillet adhesive layer 410 and an upper surface of the first chip 200 are at substantially the same height.

When the first fillet adhesive layer 410 is not interposed between the first chip 200 and the third chip 500, the liquid-phase first fillet adhesive layer 410 existing on the upper surface of the first chip 200 can entirely move in the horizontal direction X and/or Y by pressure in the vertical direction Z, which occurs in a process of attaching the third chip 500 onto the first chip 200, such that the first fillet adhesive layer 410 does not remain between the first chip 200 and the third chip 500. In this case, the first fillet adhesive layer 410 may be in contact with a portion of the side surface of the first chip 200 and a portion of the lower surface of the third chip 500 and may not be in contact with the upper surface of the first chip 200. The first fillet adhesive layer 410 may surround the first chip 200. In this case, the third chip 500 may be attached to the first chip 200 by the film adhesive layer 550. In this case, the film adhesive layer 550 may have a main role for adhesion between the first chip 200 and the third chip 500, and the first fillet adhesive layer 410 may assist in the adhesion between the first chip 200 and the third chip 500.

In some implementations, a portion of the first fillet adhesive layer 410 may remain between the first chip 200 and the third chip 500. That is, the first fillet adhesive layer 410 may remain on the upper surface of the first chip 200. In this case, the length of the first fillet adhesive layer 410 in the horizontal direction X may be greater than the length of the second fillet adhesive layer 420 in the horizontal direction X.

In a process of attaching the third chip 500 onto the upper surface of the second chip 300, the second fillet adhesive layer 420 may protrude from the upper surface of the second chip 300 in the horizontal direction X and/or Y. The second fillet adhesive layer 420 provided between the third chip 500 and the second chip 300 may protrude from the upper surface of the second chip 300 in the horizontal direction X and/or Y by pressure applied from the third chip 500 and the second chip 300 in the vertical direction Z. That is, the second fillet adhesive layer 420 may protrude from the second chip 300 in the horizontal direction X and/or Y.

The second fillet adhesive layer 420 may be between the second chip 300 and the third chip 500. The thickness of the second fillet adhesive layer 420 in the vertical direction Z may be substantially the same as the height difference T1 between the upper surface of the first chip 200 and the upper surface of the second chip 300. Both the second fillet adhesive layer 420 and the film adhesive layer 550 may be between the third chip 500 and the second chip 300.

The third chip 500 may be a semiconductor chip as a memory chip or a logic chip. The film adhesive layer 550 may be provided to the lower surface of the third chip 500. The film adhesive layer 550 may extend in the horizontal direction X. The upper and lower surfaces of the film adhesive layer 550 may have a flat shape.

The film adhesive layer 550 may be a film having self-adhesive characteristics. For example, the film adhesive layer 550 may be a double-sided adhesive film. In some implementations, the film adhesive layer 550 may be a tape-shaped material layer, e.g., planar, a liquid coating and hardening material layer, or a combination thereof. In addition, the film adhesive layer 550 may include a thermal setting structure, thermal plastic, an ultraviolet (UV) cure material, or a combination thereof. The film adhesive layer 550 may be referred to as a die attach film (DAF) or a non-conductive film (NCF).

The molding member 900 may be provided onto the upper surface of the package substrate 100 to surround the first chip 200, the second chip 300, the first fillet adhesive layer 410, the second fillet adhesive layer 420, and the third chip 500. The molding member 900 may be formed of a thermosetting resin, such as an epoxy resin, a thermoplastic resin, such as polyimide, or a resin including a reinforcing material, such as an inorganic filler, particularly, an Ajinomoto build-up film (ABF), FR-4, BT, or the like, but is not limited thereto, and the molding member 900 may be formed of a molding material, such as an epoxy molding compound (EMC), or a photosensitive material, such as a photo imageable encapsulant (PIE). In some implementations, a portion of the molding member 900 may include an insulating material, such as a silicon oxide film, a silicon nitride film, or a silicon oxynitride film.

In some conventional semiconductor packages, when the vertical level of the upper surface of the first chip 200 differs from the vertical level of the upper surface of the second chip 300, the third chip 500 is attached onto the first chip 200 and the second chip 300 through the film adhesive layer 550. In this case, to offset the height difference T1 between the first chip 200 and the second chip 300, a material having relatively small viscosity is used as the film adhesive layer 550. Accordingly, the third chip 500 may not be firmly fixed onto the first chip 200 and the second chip 300, an empty space may occur between the first chip 200 and the third chip 500 or between the second chip 300 and the third chip 500, and the third chip 500 may be attached only onto the upper surface of the first chip 200. In addition, the third chip 500 may be inclined due to the height difference T1 between the first chip 200 and the second chip 300. When an empty space occurs between the first chip 200 and the third chip 500 or between the second chip 300 and the third chip 500, the molding member 900 may permeate into the empty space, thereby weakening the structural reliability of the semiconductor package 10.

However, in the disclosed semiconductor package 10, regardless of the height difference T1 between the first chip 200 and the second chip 300, the first fillet adhesive layer 410 and the second fillet adhesive layer 420, respectively provided on the upper surface of the first chip 200 and the upper surface of the second chip 300, may attach the third chip 500 onto the first chip 200 and the second chip 300 without the third chip 500 being inclined. In addition, because the first fillet adhesive layer 410 and the second fillet adhesive layer 420 are provided in the liquid phase, even when the height difference T1 between the first chip 200 and the second chip 300 is not constant, the third chip 500 may be attached onto the first chip 200 and the second chip 300 without the third chip 500 being inclined.

Furthermore, the first fillet adhesive layer 410, which is provided on the first chip 200 that is higher than the second chip 300, protrudes from the first chip 200 only in the horizontal direction X and/or Y by pressure of the first chip 200 and the third chip 500. Thus, the total thickness of the semiconductor package 10 in the vertical direction Z does not increase, since the first fillet adhesive layer 410 does not protrude from the first chip 200 in the vertical direction Z. That is, the height of the semiconductor package 10 in the vertical direction Z may be the same as the height of an existing semiconductor package in which the third chip 500 is attached onto the first chip 200 and the second chip 300 by the film adhesive layer 550 only. As a result, the semiconductor package 10, in which the third chip 500 is attached onto the first chip 200 and the second chip 300 through the first fillet adhesive layer 410 and the second fillet adhesive layer 420, has structural stability because the molding member 900 does not permeate between chips. In addition, because the thickness of the semiconductor package 10 does not increase even when the first fillet adhesive layer 410 and the second fillet adhesive layer 420 are added to the semiconductor package 10, the reliability of the semiconductor package 10 may be improved without increasing the thickness of the semiconductor package 10. Furthermore, by using the first fillet adhesive layer 410, the second fillet adhesive layer 420, and the film adhesive layer 550, the third chip 500 may be firmly fixed onto the first chip 200 and the second chip 300, and the third chip 500 is prevented from rotating or inclining.

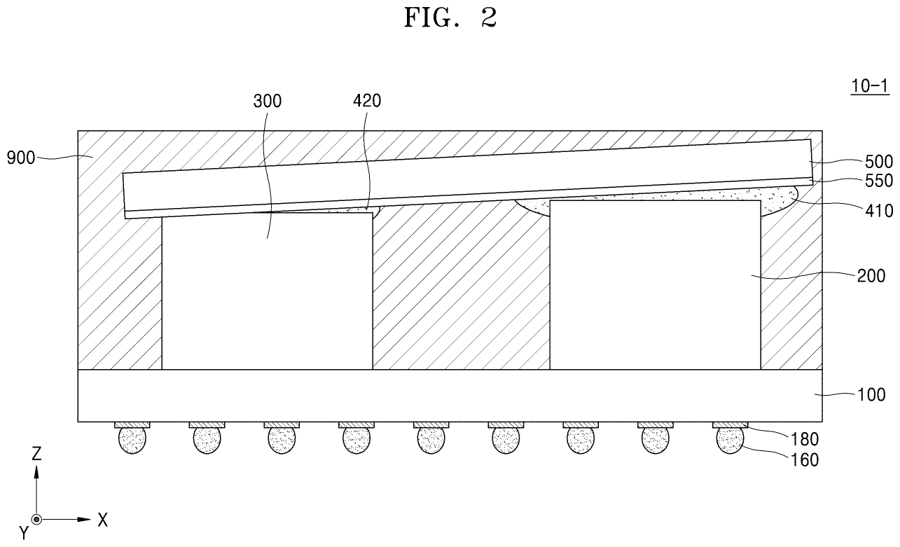

FIG. 2 is a cross-sectional view schematically illustrating another example of a semiconductor package 10-1. Hereinafter, the description made with reference to FIG. 1 is omitted, and differences from the description are mainly described.

Referring to FIG. 2, the semiconductor package 10-1 includes the package substrate 100, the first chip 200, the second chip 300, the third chip 500, the first fillet adhesive layer 410, the second fillet adhesive layer 420, the film adhesive layer 550, and the molding member 900. The package substrate 100 is a substrate on which the first chip 200 and the second chip 300 are mounted and may be beneath the first chip 200 and the second chip 300.

The first chip 200 may be on the upper surface of the package substrate 100. In some implementations, the first chip 200 may be a semiconductor chip electrically connected to the package substrate 100 or a dummy chip not electrically connected to the package substrate 100.

The second chip 300 may be on the package substrate 100 and spaced apart from the first chip 200. In some implementations, the second chip 300 may be a semiconductor chip electrically connected to the package substrate 100 or a dummy chip not electrically connected to the package substrate 100. In some implementations, the vertical level of the upper surface of the first chip 200 may be higher than the vertical level of the upper surface of the second chip 300.

The third chip 500 may be on the first chip 200 and the second chip 300. Particularly, the third chip 500 may be attached onto the first chip 200 and the second chip 300. In some implementations, the third chip 500 may be attached onto the first chip 200 and the second chip 300 in an inclined state. Particularly, the third chip 500 may be inclined at an angle so that the heights of the lower surface and the upper surface of the third chip 500 increase from an end of the third chip 500 close to the second chip 300 toward an end of the third chip 500 close to the first chip 200. In other words, the third chip 500 may be attached onto the second chip 300 and the third chip 500 in an inclined orientation, e.g., inclined toward the second chip 300.

The first fillet adhesive layer 410 may be between the third chip 500 and the first chip 200, and the second fillet adhesive layer 420 may be between the third chip 500 and the second chip 300. The first fillet adhesive layer 410 may be coated in the liquid phase on the upper surface of the first chip 200, and the second fillet adhesive layer 420 may be coated in the liquid phase on the upper surface of the second chip 300. The first fillet adhesive layer 410 and the second fillet adhesive layer 420 may include substantially the same material.

In some implementations, the first fillet adhesive layer 410 may be between the third chip 500 and the first chip 200. Because the third chip 500 is attached onto the first chip 200 in an inclined state, the first fillet adhesive layer 410 may remain between the first chip 200 and the third chip 500 regardless of the pressure between the first chip 200 and the third chip 500. The first fillet adhesive layer 410 may protrude from the upper surface of the first chip 200 in the horizontal direction X and/or Y.

The second fillet adhesive layer 420 may remain on only a portion of the upper surface of the second chip 300. Because the third chip 500 is attached onto the second chip 300 in a state of being inclined toward the second chip 300, the portion of the upper surface of the second chip 300 may be in contact with the second fillet adhesive layer 420, and the other portion of the upper surface of the second chip 300 may be in direct contact with the film adhesive layer 550. The second fillet adhesive layer 420 may protrude from the upper surface of the second chip 300 in the horizontal direction X and/or Y. In this case, the second fillet adhesive layer 420 may not protrude in a lateral direction in which the second chip 300 is in direct contact with the film adhesive layer 550.

The film adhesive layer 550 provided on the lower surface of the third chip 500 may have a shape extending in the horizontal direction X. However, because the third chip 500 is provided onto the first chip 200 and the second chip 300 in a state of being inclined toward the second chip 300, the film adhesive layer 550 may also be provided in the state of being inclined toward the second chip 300. The upper and lower surfaces of the film adhesive layer 550 may have a flat shape.

The molding member 900 may be provided onto the upper surface of the package substrate 100 and surround the first chip 200, the second chip 300, the first fillet adhesive layer 410, the second fillet adhesive layer 420, and the third chip 500. The molding member 900 may not be between the third chip 500 and the first chip 200 and between the third chip 500 and the second chip 300.

In the semiconductor package 10-1, the third chip 500 may be attached onto the first chip 200 and the second chip 300 through the first fillet adhesive layer 410 and the second fillet adhesive layer 420. Accordingly, even when the third chip 500 is attached onto the first chip 200 and the second chip 300 in an inclined state, an empty space may not be formed but filled with the first fillet adhesive layer 410 and the second fillet adhesive layer 420 between the third chip 500 and the first chip 200 and between the third chip 500 and the second chip 300. The third chip 500 adheres to the first chip 200 and the second chip 300 by the first fillet adhesive layer 410 and the second fillet adhesive layer 420 in the liquid phase. Accordingly, the molding member 900 may be prevented from permeating between the third chip 500 and the first chip 200 and between the third chip 500 and the second chip 300, which would weaken the structural reliability of the semiconductor package 10-1.

FIG. 3 is a cross-sectional view schematically illustrating another example of a semiconductor package 11. Hereinafter, the description made with reference to FIGS. 1 and 2 is omitted, and differences from the description are mainly described.

Referring to FIG. 3, the semiconductor package 11 includes the package substrate 100, the first chip 200, the second chip 300, the third chip 500, the first fillet adhesive layer 410, the second fillet adhesive layer 420, the film adhesive layer 550, and the molding member 900. The package substrate 100 is a substrate on which the first chip 200 and the second chip 300 are mounted and may be beneath the first chip 200 and the second chip 300.

The first chip 200 may be on the upper surface of the package substrate 100. The second chip 300 may be on the package substrate 100 and spaced apart from the first chip 200 in the horizontal direction X or Y. The vertical level of the upper surface of the first chip 200 may be higher than the vertical level of the upper surface of the second chip 300.

In some implementations, the first chip 200 may be a dummy chip, and the second chip 300 may be a semiconductor chip. The first chip 200 may not be electrically connected to the package substrate 100. The second chip 300 may be mounted on the package substrate 100 in a flip chip manner through a chip connection bump 350, such as a microbump. The chip connection bump 350 may be electrically connected to each of a second chip pad 320 and a package substrate pad 140. In some implementations, an under-fill material layer 390 surrounding the chip connection bump 350 may be between the second chip 300 and the package substrate 100. The under-fill material layer 390 may include an epoxy resin formed by, for example, a capillary under-fill process. However, in some implementations, the molding member 900 may directly fill the gap between the second chip 300 and the package substrate 100 by a molded under-fill process. In this case, the under-fill material layer 390 may be omitted.

The third chip 500 may be on the first chip 200 and the second chip 300. Particularly, the third chip 500 may be attached onto the first chip 200 and the second chip 300. In some implementations, the third chip 500 may be attached onto the first chip 200 and the second chip 300 in a horizontal manner, e.g., without being inclined. In this case, the third chip 500 may be attached onto the first chip 200 and the second chip 300 through the first fillet adhesive layer 410, the second fillet adhesive layer 420, and the film adhesive layer 550. Particularly, the first fillet adhesive layer 410 may not be between the third chip 500 and the first chip 200, and the second fillet adhesive layer 420 may be between the third chip 500 and the second chip 300. This is substantially the same as or similar to that described with reference to FIG. 1, and thus, a detailed description thereof is omitted.

In some implementations, the third chip 500 may be attached onto the first chip 200 and the second chip 300 in an inclined state. In this case, the first fillet adhesive layer 410 may be between the third chip 500 and the first chip 200, and the second fillet adhesive layer 420 may be between the third chip 500 and the second chip 300. This is substantially the same as or similar to that described with reference to FIG. 2, and thus, a detailed description thereof is omitted.

The molding member 900 may be provided onto the upper surface of the package substrate 100 to surround the first chip 200, the second chip 300, the first fillet adhesive layer 410, the second fillet adhesive layer 420, and the third chip 500. The molding member 900 may not be between the third chip 500 and the first chip 200 and between the third chip 500 and the second chip 300. That is, the interface between the third chip 500 and the first chip 200 is free of the molding member 900, and the interface between the third chip 500 and the second chip 300 is free of the molding member 900. Rather, an entire upper surface of the first chip 200 contacts the film adhesive layer 550, and an entire upper surface of the second chip 300 contacts the second fillet adhesive layer 420.

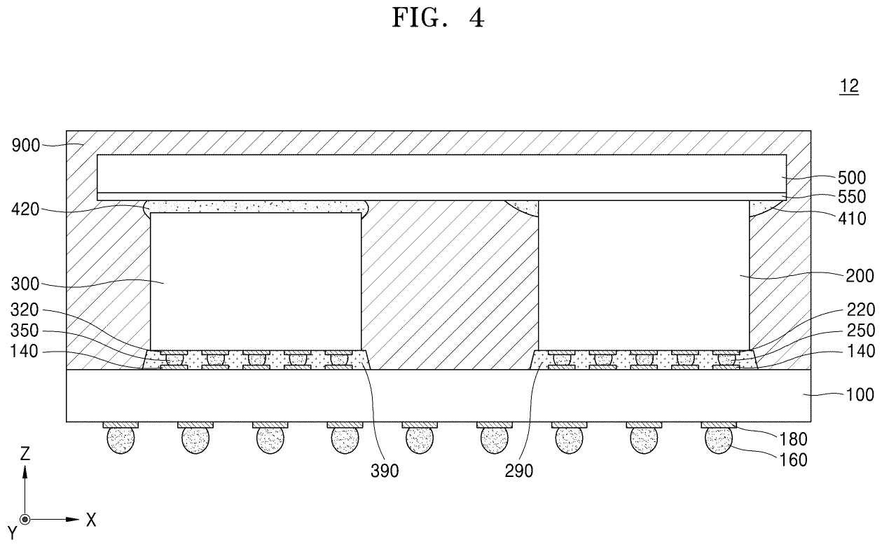

FIG. 4 is a cross-sectional view schematically illustrating another example of a semiconductor package 12. Hereinafter, the description made with reference to FIGS. 1 to 3 is omitted, and differences from the description are mainly described.

Referring to FIG. 4, the semiconductor package 12 includes the package substrate 100, the first chip 200, the second chip 300, the third chip 500, the first fillet adhesive layer 410, the second fillet adhesive layer 420, the film adhesive layer 550, and the molding member 900. The package substrate 100 is a substrate on which the first chip 200 and the second chip 300 are mounted and may be beneath the first chip 200 and the second chip 300.

The first chip 200 may be on the upper surface of the package substrate 100. The second chip 300 may be on the package substrate 100 and spaced apart from the first chip 200 in the horizontal direction X or Y.

In some implementations, each of the first chip 200 and the second chip 300 may be a semiconductor chip. The first chip 200 may be mounted on the package substrate 100 in a flip chip manner through a chip connection bump 250, such as a microbump. The chip connection bump 250 may be electrically connected to each of a first chip pad 220 and the package substrate pad 140. In some implementations, an under-fill material layer 290 surrounding the chip connection bump 250 may be between the first chip 200 and the package substrate 100. The under-fill material layer 290 may include an epoxy resin formed by, for example, a capillary under-fill process. However, in some implementations, the molding member 900 may directly fill the gap between the first chip 200 and the package substrate 100 by a molded under-fill process. In this case, the under-fill material layer 290 may be omitted.

The second chip 300 may be mounted on the package substrate 100 in a flip chip manner through the chip connection bump 350, such as a microbump. The chip connection bump 350 may be electrically connected to each of the second chip pad 320 and the package substrate pad 140. In some implementations, the under-fill material layer 390 surrounding the chip connection bump 350 may be between the second chip 300 and the package substrate 100. The under-fill material layer 390 may include an epoxy resin formed by, for example, a capillary under-fill process. However, in some implementations, the molding member 900 may directly fill the gap between the second chip 300 and the package substrate 100 by a molded under-fill process. In this case, the under-fill material layer 390 may be omitted.

The third chip 500 may be on the first chip 200 and the second chip 300. Particularly, the third chip 500 may be attached onto the first chip 200 and the second chip 300. In some implementations, the third chip 500 may be attached onto the first chip 200 and the second chip 300 in a horizontal manner, e.g., without being inclined. In this case, the third chip 500 may be attached onto the first chip 200 and the second chip 300 through the first fillet adhesive layer 410, the second fillet adhesive layer 420, and the film adhesive layer 550. Particularly, the first fillet adhesive layer 410 may not be between the third chip 500 and the first chip 200, and the second fillet adhesive layer 420 may be between the third chip 500 and the second chip 300. This is substantially the same as or similar to that described with reference to FIG. 1, and thus, a detailed description thereof is omitted.

In some implementations, the third chip 500 may be attached onto the first chip 200 and the second chip 300 in an inclined state. In this case, the first fillet adhesive layer 410 may be between the third chip 500 and the first chip 200, and the second fillet adhesive layer 420 may be between the third chip 500 and the second chip 300. This is substantially the same as or similar to that described with reference to FIG. 2, and thus, a detailed description thereof is omitted.

The molding member 900 may be provided onto the upper surface of the package substrate 100 to surround the first chip 200, the second chip 300, the first fillet adhesive layer 410, the second fillet adhesive layer 420, and the third chip 500. The molding member 900 may not be between the third chip 500 and the first chip 200 and between the third chip 500 and the second chip 300.

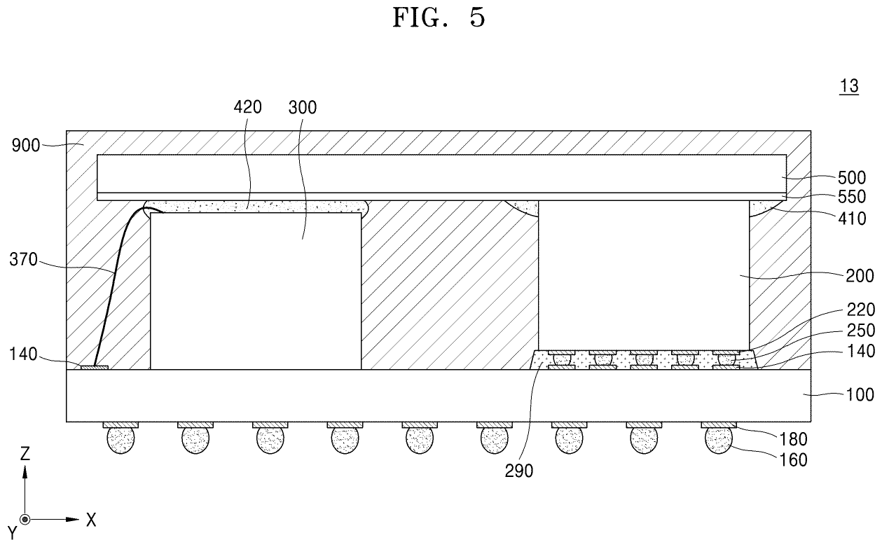

FIG. 5 is a cross-sectional view schematically illustrating another example of a semiconductor package 13. Hereinafter, the description made with reference to FIGS. 1 to 4 is omitted, and differences from the description are mainly described.

Referring to FIG. 5, the semiconductor package 13 includes the package substrate 100, the first chip 200, the second chip 300, the third chip 500, the first fillet adhesive layer 410, the second fillet adhesive layer 420, the film adhesive layer 550, and the molding member 900. The package substrate 100 is a substrate on which the first chip 200 and the second chip 300 are mounted and may be beneath the first chip 200 and the second chip 300.

The first chip 200 may be on the upper surface of the package substrate 100. The second chip 300 may be on the package substrate 100 and spaced apart from the first chip 200 in the horizontal direction X or Y.

In some implementations, each of the first chip 200 and the second chip 300 may be a semiconductor chip. The first chip 200 may be mounted on the package substrate 100 in a flip chip manner through the chip connection bump 250, such as a microbump. The chip connection bump 250 may be electrically connected to each of the first chip pad 220 and the package substrate pad 140. In some implementations, the under-fill material layer 290 surrounding the chip connection bump 250 may be between the first chip 200 and the package substrate 100. The under-fill material layer 290 may include an epoxy resin formed by, for example, a capillary under-fill process. However, in some implementations, the molding member 900 may directly fill the gap between the first chip 200 and the package substrate 100 by a molded under-fill process. In this case, the under-fill material layer 290 may be omitted.

The second chip 300 may be electrically connected to the package substrate 100 via a wiring 370. Particularly, the second chip 300 may be electrically connected to the package substrate 100 via the wiring 370 and the package substrate pad 140, the wiring 370 being connected to a pad on the upper surface of the second chip 300.

The third chip 500 may be on the first chip 200 and the second chip 300. Particularly, the third chip 500 may be attached onto the first chip 200 and the second chip 300. In some implementations, the third chip 500 may be attached onto the first chip 200 and the second chip 300 in a horizontal manner. In this case, the third chip 500 may be attached onto the first chip 200 and the second chip 300 through the first fillet adhesive layer 410, the second fillet adhesive layer 420, and the film adhesive layer 550. Particularly, the first fillet adhesive layer 410 may not be between the third chip 500 and the first chip 200, and the second fillet adhesive layer 420 may be between the third chip 500 and the second chip 300. This is substantially the same as or similar to that described with reference to FIG. 1, and thus, a detailed description thereof is omitted.

In some implementations, the third chip 500 may be attached onto the first chip 200 and the second chip 300 in an inclined state. In this case, the first fillet adhesive layer 410 may be between the third chip 500 and the first chip 200, and the second fillet adhesive layer 420 may be between the third chip 500 and the second chip 300. This is substantially the same as or similar to that described with reference to FIG. 2, and thus, a detailed description thereof is omitted.

The molding member 900 may be provided onto the upper surface of the package substrate 100 to surround the first chip 200, the second chip 300, the first fillet adhesive layer 410, the second fillet adhesive layer 420, and the third chip 500. The molding member 900 may not be between the third chip 500 and the first chip 200 and between the third chip 500 and the second chip 300.

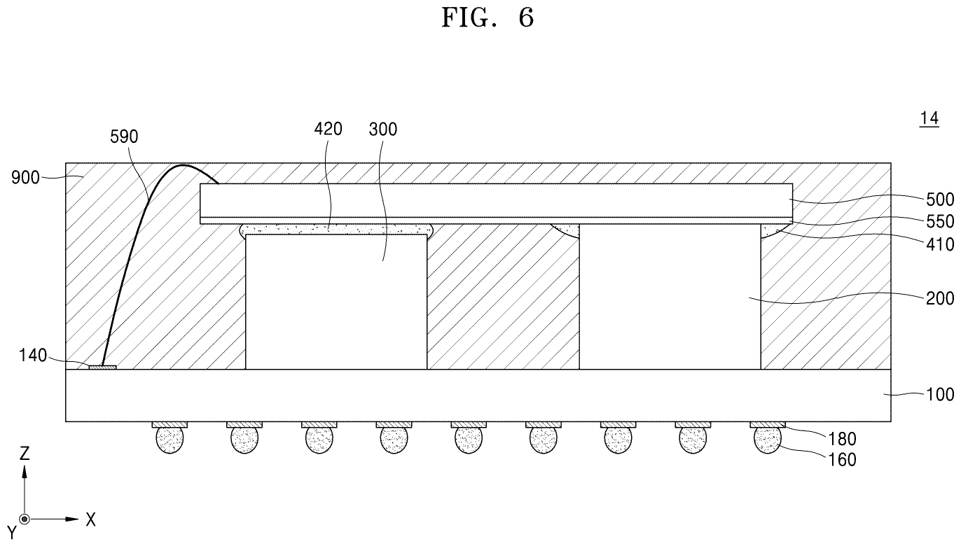

FIG. 6 is a cross-sectional view schematically illustrating another example of a semiconductor package 14. Hereinafter, the description made with reference to FIGS. 1 to 5 is omitted, and differences from the description are mainly described.

Referring to FIG. 6, the semiconductor package 14 includes the package substrate 100, the first chip 200, the second chip 300, the third chip 500, the first fillet adhesive layer 410, the second fillet adhesive layer 420, the film adhesive layer 550, and the molding member 900. The package substrate 100 is a substrate on which the first chip 200 and the second chip 300 are mounted and may be beneath the first chip 200 and the second chip 300.

The first chip 200 may be on the upper surface of the package substrate 100. In some implementations, the first chip 200 may be a semiconductor chip electrically connected to the package substrate 100 or a dummy chip not electrically connected to the package substrate 100.

The second chip 300 may be on the package substrate 100 and spaced apart from the first chip 200. In some implementations, the second chip 300 may be a semiconductor chip electrically connected to the package substrate 100 or a dummy chip not electrically connected to the package substrate 100. In some implementations, the vertical level of the upper surface of the first chip 200 may be higher than the vertical level of the upper surface of the second chip 300.

The third chip 500 may be on the first chip 200 and the second chip 300. Particularly, the third chip 500 may be attached onto the first chip 200 and the second chip 300. In some implementations, the third chip 500 may be attached onto the first chip 200 and the second chip 300 in a horizontal manner. In this case, the third chip 500 may be attached onto the first chip 200 and the second chip 300 through the first fillet adhesive layer 410, the second fillet adhesive layer 420, and the film adhesive layer 550. Particularly, the first fillet adhesive layer 410 may not be between the third chip 500 and the first chip 200, and the second fillet adhesive layer 420 may be between the third chip 500 and the second chip 300. This is substantially the same as or similar to that described with reference to FIG. 1, and thus, a detailed description thereof is omitted.

In some implementations, the third chip 500 may be attached onto the first chip 200 and the second chip 300 in an inclined state. In this case, the first fillet adhesive layer 410 may be between the third chip 500 and the first chip 200, and the second fillet adhesive layer 420 may be between the third chip 500 and the second chip 300. This is substantially the same as or similar to that described with reference to FIG. 2, and thus, a detailed description thereof is omitted.

The second chip 300 may be electrically connected to the package substrate 100 via a wiring 590. Particularly, the second chip 300 may be electrically connected to the package substrate 100 via the wiring 590 and the package substrate pad 140, the wiring 590 being connected to a pad on the upper surface of the second chip 300.

The molding member 900 may be provided onto the upper surface of the package substrate 100 to surround the first chip 200, the second chip 300, the first fillet adhesive layer 410, the second fillet adhesive layer 420, and the third chip 500. The molding member 900 may not be between the third chip 500 and the first chip 200 and between the third chip 500 and the second chip 300.

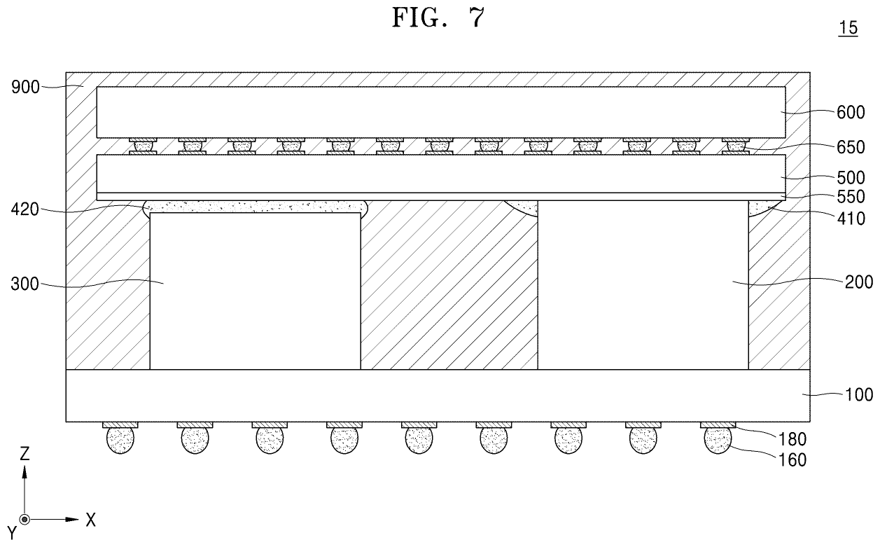

FIG. 7 is a cross-sectional view schematically illustrating another example of a semiconductor package 15. Hereinafter, the description made with reference to FIGS. 1 to 6 is omitted, and differences from the description are mainly described.

Referring to FIG. 7, the semiconductor package 15 includes the package substrate 100, the first chip 200, the second chip 300, the third chip 500, a fifth chip 600, the first fillet adhesive layer 410, the second fillet adhesive layer 420, the film adhesive layer 550, and the molding member 900. The package substrate 100 is a substrate on which the first chip 200 and the second chip 300 are mounted and may be beneath the first chip 200 and the second chip 300.

The first chip 200 may be on the upper surface of the package substrate 100. In some implementations, the first chip 200 may be a semiconductor chip electrically connected to the package substrate 100 or a dummy chip not electrically connected to the package substrate 100.

The second chip 300 may be on the package substrate 100 and spaced apart from the first chip 200. In some implementations, the second chip 300 may be a semiconductor chip electrically connected to the package substrate 100 or a dummy chip not electrically connected to the package substrate 100. In some implementations, the vertical level of the upper surface of the first chip 200 may be higher than the vertical level of the upper surface of the second chip 300.

The third chip 500 may be on the first chip 200 and the second chip 300. The third chip 500 may be attached onto the first chip 200 and the second chip 300. In some implementations, the third chip 500 may be attached onto the first chip 200 and the second chip 300 in a horizontal manner. In this case, the third chip 500 may be attached onto the first chip 200 and the second chip 300 through the first fillet adhesive layer 410, the second fillet adhesive layer 420, and the film adhesive layer 550. Particularly, the first fillet adhesive layer 410 may not be between the third chip 500 and the first chip 200, and the second fillet adhesive layer 420 may be between the third chip 500 and the second chip 300. This is substantially the same as or similar to that described with reference to FIG. 1, and thus, a detailed description thereof is omitted.

In some implementations, the third chip 500 may be attached onto the first chip 200 and the second chip 300 in an inclined state. In this case, the first fillet adhesive layer 410 may be between the third chip 500 and the first chip 200, and the second fillet adhesive layer 420 may be between the third chip 500 and the second chip 300. This is substantially the same as or similar to that described with reference to FIG. 2, and thus, a detailed description thereof is omitted.

The fifth chip 600 may be mounted on the third chip 500. In some implementations, the fifth chip 600 may be connected to the third chip 500 through a chip connection bump 650 in a flip chip manner. The fifth chip 600 may be electrically connected to the third chip 500. In some implementations, the fifth chip 600 may be electrically connected to the package substrate 100 via a wiring.

The molding member 900 may be provided onto the upper surface of the package substrate 100 to surround the first chip 200, the second chip 300, the first fillet adhesive layer 410, the second fillet adhesive layer 420, the third chip 500, and the fifth chip 600. The molding member 900 may not be between the third chip 500 and the first chip 200 and between the third chip 500 and the second chip 300.

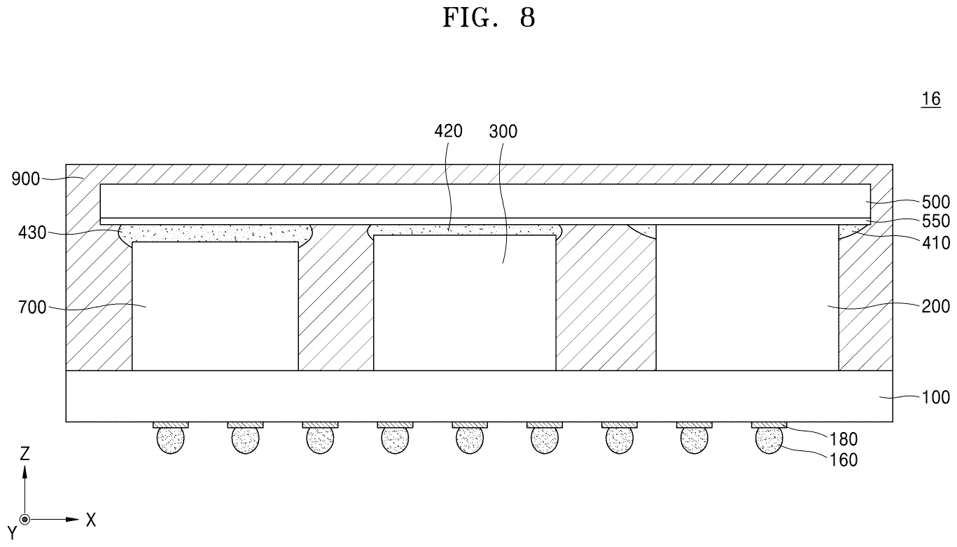

FIG. 8 is a cross-sectional view schematically illustrating another example of a semiconductor package 16. Hereinafter, the description made with reference to FIGS. 1 to 7 is omitted, and differences from the description are mainly described.

Referring to FIG. 8, the semiconductor package 16 includes the package substrate 100, the first chip 200, the second chip 300, the third chip 500, a fourth chip 700, the first fillet adhesive layer 410, the second fillet adhesive layer 420, a third fillet adhesive layer 430, the film adhesive layer 550, and the molding member 900. The package substrate 100 is a substrate on which the first chip 200 the second chip 300, and the fourth chip 700 are mounted, and may be beneath the first chip 200 the second chip 300, and the fourth chip 700.

The first chip 200 may be on the upper surface of the package substrate 100. In some implementations, the first chip 200 may be a semiconductor chip electrically connected to the package substrate 100 or a dummy chip not electrically connected to the package substrate 100.

The second chip 300 may be on the package substrate 100 and spaced apart from the first chip 200. In some implementations, the second chip 300 may be a semiconductor chip electrically connected to the package substrate 100 or a dummy chip not electrically connected to the package substrate 100. In some implementations, the vertical level of the upper surface of the first chip 200 may be higher than the vertical level of the upper surface of the second chip 300.

The fourth chip 700 may be on the package substrate 100 and spaced apart from the first chip 200 and the second chip 300. The fourth chip 700 may be spaced apart from the first chip 200 in the horizontal direction X with the second chip 300 therebetween. In some implementations, the fourth chip 700 may be a semiconductor chip electrically connected to the package substrate 100 or a dummy chip not electrically connected to the package substrate 100. In some implementations, the vertical level of the upper surface of the second chip 300 may be higher than the vertical level of the upper surface of the fourth chip 700.

The third chip 500 may be on the first chip 200, the second chip 300, and the fourth chip 700. The third chip 500 may be attached onto the first chip 200, the second chip 300, and the fourth chip 700. In some implementations, the third chip 500 may be attached onto the first chip 200, the second chip 300, and the fourth chip 700 in a horizontal manner. In this case, the third chip 500 may be attached onto the first chip 200, the second chip 300, and the fourth chip 700 through the first fillet adhesive layer 410, the second fillet adhesive layer 420, the third fillet adhesive layer 430, and the film adhesive layer 550. Particularly, the first fillet adhesive layer 410 may not be between the third chip 500 and the first chip 200, the second fillet adhesive layer 420 may be between the third chip 500 and the second chip 300, and the third fillet adhesive layer 430 may be between the third chip 500 and the fourth chip 700. The third fillet adhesive layer 430 may also be an adhesive layer formed by coating the upper surface of the fourth chip 700 with a liquid adhesive and then hardening the liquid adhesive.

In some implementations, the thickness of the second fillet adhesive layer 420 in the vertical direction Z may be less than the thickness of the third fillet adhesive layer 430 in the vertical direction Z, and the length of the second fillet adhesive layer 420 in the horizontal direction X may be greater than the length of the third fillet adhesive layer 430 in the horizontal direction X.

In some implementations, the third chip 500 may be attached onto the first chip 200, the second chip 300, and the fourth chip 700 in an inclined state. In this case, the first fillet adhesive layer 410 may be between the third chip 500 and the first chip 200, the second fillet adhesive layer 420 may be between the third chip 500 and the second chip 300, and the third fillet adhesive layer 430 may be between the third chip 500 and the fourth chip 700.

The molding member 900 may be provided onto the upper surface of the package substrate 100 to surround the first chip 200, the second chip 300, the fourth chip 700, the first fillet adhesive layer 410, the second fillet adhesive layer 420, the third fillet adhesive layer 430, and the third chip 500. The molding member 900 may not be between the third chip 500 and the first chip 200, between the third chip 500 and the second chip 300, and between the third chip 500 and the fourth chip 700. That is, the interface between the third chip 500 and the first chip 200, the interface between the third chip 500 and the second chip 300, and the interface between the third chip 500 and the fourth chip 700 are free of the molding member 900. Rather, an entire lower surface of each the first chip 200, the second chip 300, and the fourth chip 700 contacts the third chip 500.

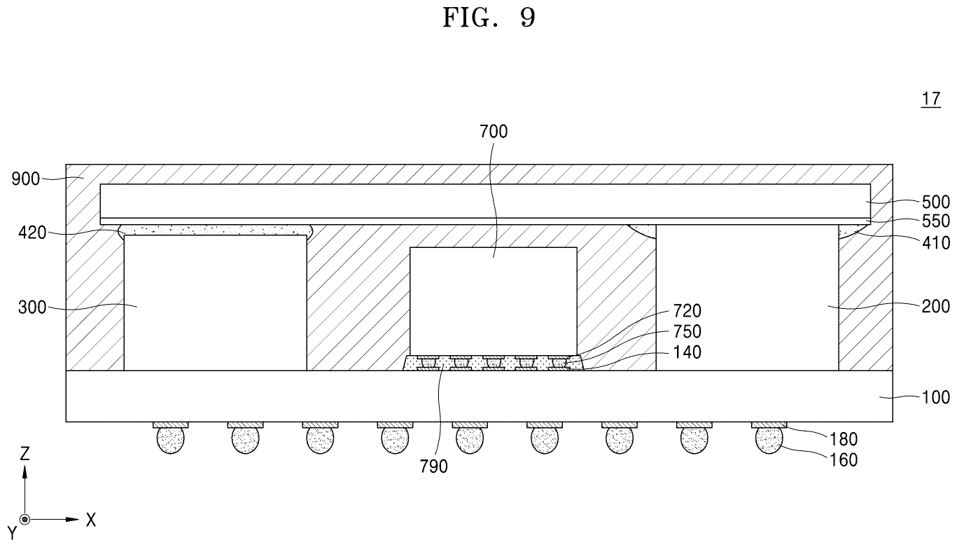

FIG. 9 is a cross-sectional view schematically illustrating another example of a semiconductor package 17. Hereinafter, the description made with reference to FIGS. 1 to 8 is omitted, and differences from the description are mainly described.

Referring to FIG. 9, the semiconductor package 17 includes the package substrate 100, the first chip 200, the second chip 300, the third chip 500, the fourth chip 700, the first fillet adhesive layer 410, the second fillet adhesive layer 420, the third fillet adhesive layer 430, the film adhesive layer 550, and the molding member 900. The package substrate 100 is a substrate on which the first chip 200 the second chip 300, and the fourth chip 700 are mounted, and may be beneath the first chip 200 the second chip 300, and the fourth chip 700.

The first chip 200 may be on the upper surface of the package substrate 100. In some implementations, the first chip 200 may be a semiconductor chip electrically connected to the package substrate 100 or a dummy chip electrically not connected to the package substrate 100.

The second chip 300 may be on the package substrate 100 and spaced apart from the first chip 200. In some implementations, the second chip 300 may be a semiconductor chip electrically connected to the package substrate 100 or a dummy chip electrically not connected to the package substrate 100. In some implementations, the vertical level of the upper surface of the first chip 200 may be higher than the vertical level of the upper surface of the second chip 300.

The fourth chip 700 may be on the package substrate 100 and spaced apart from the first chip 200 and the second chip 300. The fourth chip 700 may be between the first chip 200 and the second chip 300. The fourth chip 700 may be a semiconductor chip electrically connected to the package substrate 100.

The fourth chip 700 may be mounted on the package substrate 100 in a flip chip manner through a chip connection bump 750, such as a microbump. The chip connection bump 750 may be electrically connected to each of the fourth chip pad 720 and the package substrate pad 140. In some implementations, an under-fill material layer 790 surrounding the chip connection bump 750 may be between the fourth chip 700 and the package substrate 100. The under-fill material layer 790 may include an epoxy resin formed by, for example, a capillary under-fill process. However, in some implementations, the molding member 900 may directly fill the gap between the fourth chip 700 and the package substrate 100 by a molded under-fill process. In this case, the under-fill material layer 790 may be omitted.

The third chip 500 may be on the first chip 200 and the second chip 300. Particularly, the third chip 500 may be attached onto the first chip 200 and the second chip 300. In some implementations, the third chip 500 may be attached onto the first chip 200 and the second chip 300 in a horizontal manner. In this case, the third chip 500 may be attached onto the first chip 200 and the second chip 300 through the first fillet adhesive layer 410, the second fillet adhesive layer 420, and the film adhesive layer 550. Particularly, the first fillet adhesive layer 410 may not be between the third chip 500 and the first chip 200, and the second fillet adhesive layer 420 may be between the third chip 500 and the second chip 300. This is substantially the same as or similar to that described with reference to FIG. 1, and thus, a detailed description thereof is omitted.

In some implementations, the third chip 500 may be attached onto the first chip 200 and the second chip 300 in an inclined state. In this case, the first fillet adhesive layer 410 may be between the third chip 500 and the first chip 200, and the second fillet adhesive layer 420 may be between the third chip 500 and the second chip 300. This is substantially the same as or similar to that described with reference to FIG. 2, and thus, a detailed description thereof is omitted.

The molding member 900 may be provided onto the upper surface of the package substrate 100 to surround the first chip 200, the second chip 300, the fourth chip 700, the first fillet adhesive layer 410, the second fillet adhesive layer 420, and the third chip 500. The molding member 900 may not be between the third chip 500 and the first chip 200 and between the third chip 500 and the second chip 300.

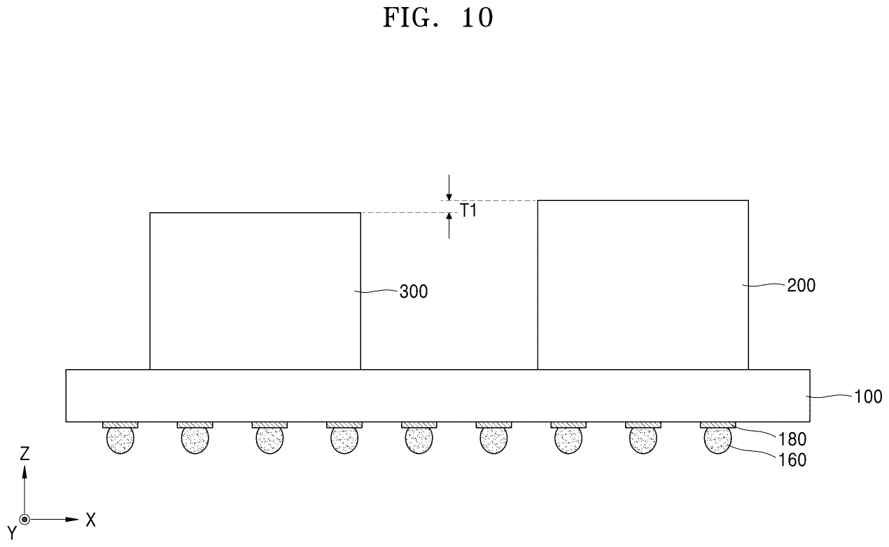

FIGS. 10 to 14 are cross-sectional views of a method of manufacturing the semiconductor package 10 of FIG. 1. Hereinafter, the description made with reference to FIGS. 1 to 9 is omitted, and differences from the description are mainly described.

First, referring to FIG. 10, the first chip 200 and the second chip 300 are mounted on the package substrate 100. Each of the first chip 200 and the second chip 300 may be a dummy chip or a semiconductor chip. The vertical level of the upper surface of the first chip 200 may be higher than the vertical level of the upper surface of the second chip 300. The height difference T1 between the upper surface of the first chip 200 and the upper surface of the second chip 300 may be within a range of 10 μm to 100 μm.

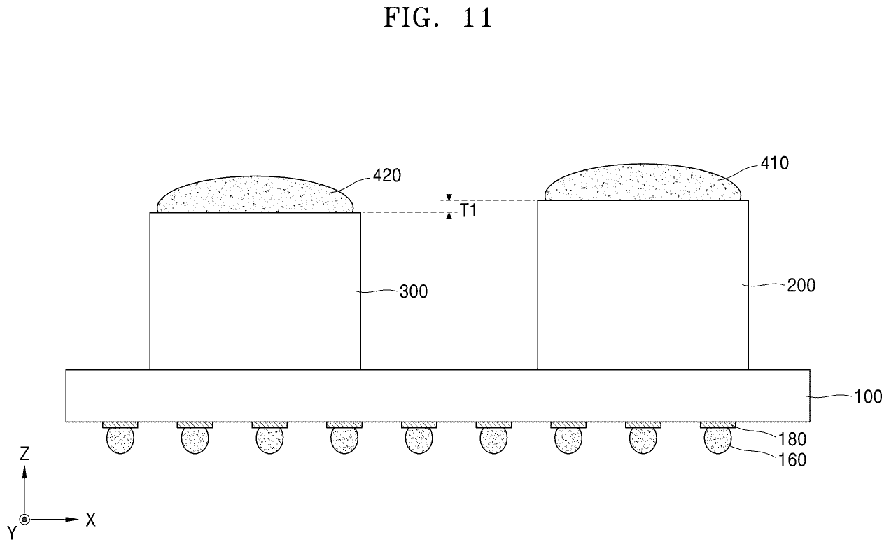

Referring to FIG. 11, the first fillet adhesive layer 410 is coated on the upper surface of the first chip 200, and the second fillet adhesive layer 420 is coated on the upper surface of the second chip 300. In this case, each of the first fillet adhesive layer 410 and the second fillet adhesive layer 420 may be a liquid adhesive. The first fillet adhesive layer 410 and the second fillet adhesive layer 420 may include substantially the same material.

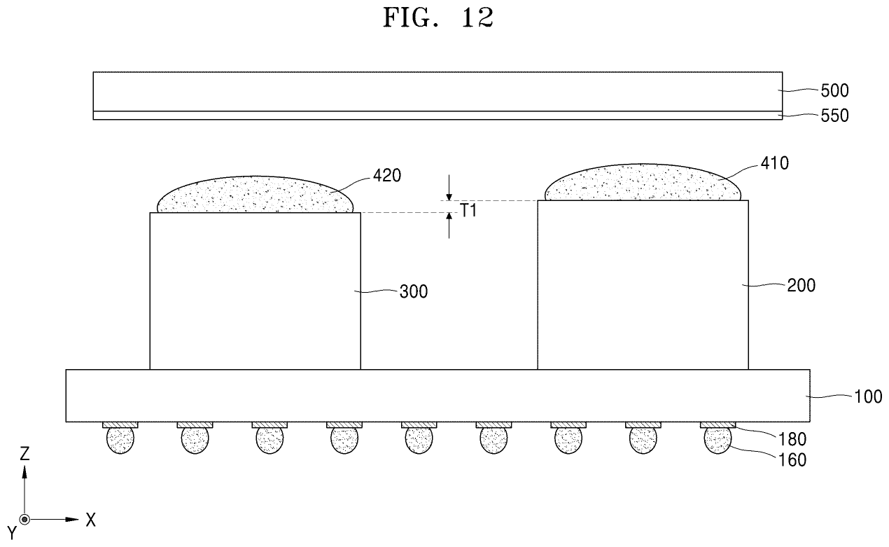

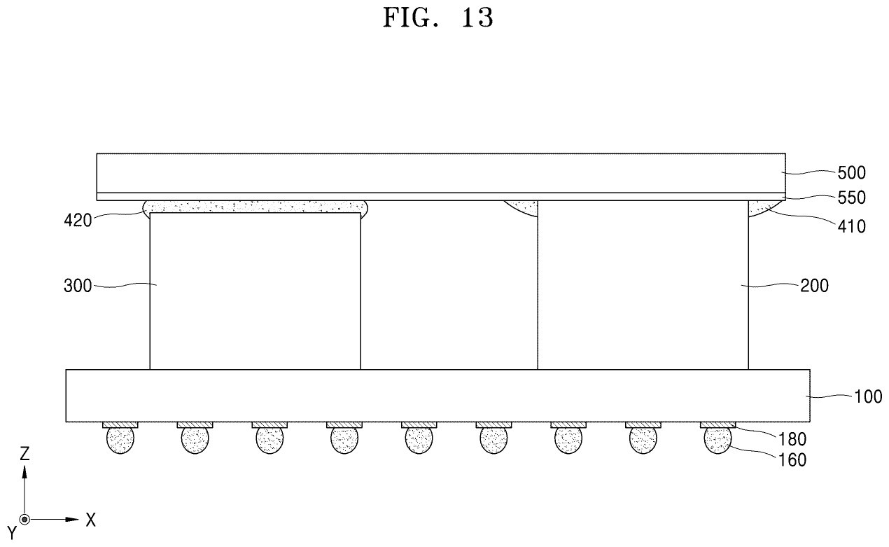

Referring to FIGS. 12 and 13, the third chip 500 having the film adhesive layer 550 attached to the lower surface thereof is attached onto the first chip 200 and the second chip 300. In this case, the first fillet adhesive layer 410 and the second fillet adhesive layer 420 may protrude in the horizontal direction X and/or Y by pressure applied by the third chip 500 to the first chip 200 and the second chip 300. In some implementations, the first fillet adhesive layer 410 may not remain on the upper surface of the first chip 200, due to the pressure applied between the third chip 500 and the first chip 200 in the vertical direction Z. However, the second fillet adhesive layer 420 may protrude in the horizontal direction X and/or Y by the pressure applied between the third chip 500 and the second chip 300 in the vertical direction Z and remain between the third chip 500 and the second chip 300. The outcome may depend on the difference between the vertical level of the upper surface of the first chip 200 and the vertical level of the upper surface of the second chip 300. As a result, the upper surface of the first chip 200 may be in contact with the film adhesive layer 550, and the upper surface of the second chip 300 may be in contact with the second fillet adhesive layer 420.

Thereafter, an operation of attaching the third chip 500 onto the upper surface of the first chip 200 and the upper surface of the second chip 300 by hardening the first fillet adhesive layer 410 and the second fillet adhesive layer 420 ends.

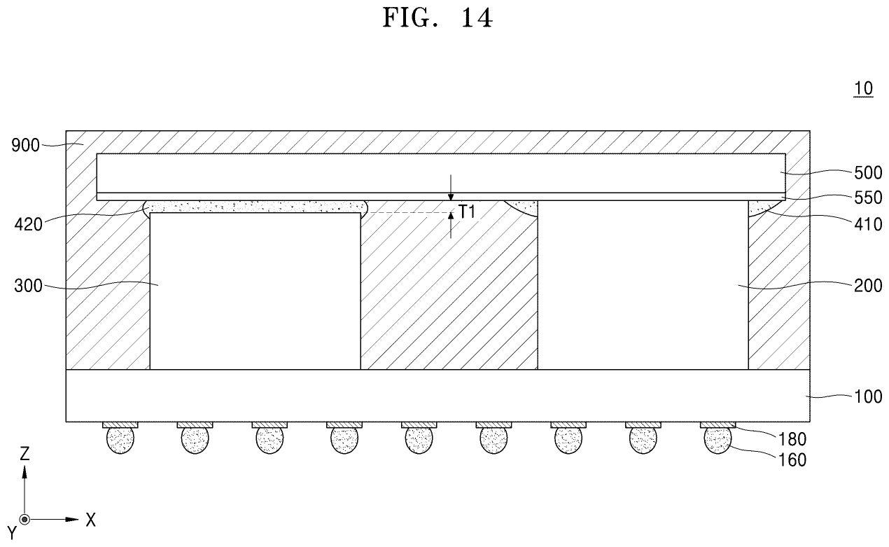

Referring to FIG. 14, the molding member 900 is coated on the upper surface of the package substrate 100. The molding member 900 may be formed to surround the first chip 200, the second chip 300, the third chip 500, the first fillet adhesive layer 410, the second fillet adhesive layer 420, and the film adhesive layer 550. The molding member 900 may not be between the third chip 500 and the first chip 200 and between the third chip 500 and the second chip 300.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the inventive concept has been particularly shown and described with reference to embodiments thereof, it will be understood that various changes in form and details may be made therein without departing from the spirit and scope of the following claims.

1. A semiconductor package comprising:
a package substrate;
a first chip on the package substrate;
a second chip on the package substrate and spaced apart from the first chip in a horizontal direction;
a third chip disposed on the first chip and the second chip along a vertical direction;
a first fillet adhesive layer surrounding a side surface of the first chip and in contact with a portion of a lower surface of the third chip; and
a second fillet adhesive layer between the second chip and the third chip,
wherein a vertical level of an upper surface of the first chip is higher than a vertical level of an upper surface of the second chip, and the second fillet adhesive layer protrudes from the upper surface of the second chip in the horizontal direction.

2. The semiconductor package of claim 1, wherein an interface between the first chip and the third chip is free of the first fillet adhesive layer.

3. The semiconductor package of claim 1, wherein the first fillet adhesive layer and the second fillet adhesive layer include a hardened liquid adhesive.

4. The semiconductor package of claim 1, wherein the first fillet adhesive layer protrudes from the upper surface of the first chip in the horizontal direction, and the second fillet adhesive layer protrudes from the upper surface of the second chip in the horizontal direction.

5. The semiconductor package of claim 1, further comprising a molding member on an upper surface of the package substrate and surrounding the first chip, the second chip, and the third chip,
wherein an interface between the first chip and the third chip is free of the molding member.

6. The semiconductor package of claim 1, wherein the third chip is attached to the first chip and the second chip, and a longitudinal direction of the third chip is substantially perpendicular to a height direction of each of the first chip and the second chip.

7. The semiconductor package of claim 1, wherein the first chip includes a dummy chip electrically insulated from the package substrate, and the second chip includes a semiconductor chip electrically connected to the package substrate.

8. The semiconductor package of claim 7, wherein the second chip is mounted on the package substrate in a flip chip manner.

9. The semiconductor package of claim 7, wherein the second chip is electrically connected to the package substrate via wiring.

10. The semiconductor package of claim 1, further comprising a fourth chip between the first chip and the second chip and electrically connected to the package substrate.

11. The semiconductor package of claim 1, wherein a fifth chip is mounted on an upper surface of the third chip.

12. The semiconductor package of claim 1, wherein a height difference between the upper surface of the first chip and the upper surface of the second chip is within a range of 10 μm to 100 μm.

13. A semiconductor package comprising:
a package substrate;
a first chip on the package substrate;
a second chip on the package substrate and spaced apart from the first chip in a horizontal direction;
a third chip having, wherein the third chip is disposed on the first chip and the second chip along a vertical direction;
a first fillet adhesive layer between the first chip and the third chip; and
a second fillet adhesive layer between the second chip and the third chip,
wherein the third chip is disposed on the first chip and the second chip in an orientation inclined toward the second chip,
wherein a vertical level of an upper surface of the first chip is higher than a vertical level of an upper surface of the second chip,
wherein the first fillet adhesive layer protrudes from the upper surface of the first chip in the horizontal direction, and
wherein the second fillet adhesive layer protrudes from the upper surface of the second chip in the horizontal direction.

14. The semiconductor package of claim 13, wherein the first chip and the second chip include semiconductor chips.

15. The semiconductor package of claim 13, wherein the third chip is electrically connected to the package substrate via wiring.

16. The semiconductor package of claim 13, further comprising:
a fourth chip on the package substrate and spaced apart from the first chip and the second chip; and
a third fillet adhesive layer on the fourth chip,
wherein the third chip is attached to the first chip, the second chip, and the fourth chip, and the third fillet adhesive layer is between the third chip and the fourth chip.

17. The semiconductor package of claim 16, further comprising a molding member on the upper surface of the package substrate and surrounding the first chip, the second chip, the third chip, and the fourth chip,
wherein each of a first interface between the third chip and the first chip, a second interface between the third chip and the second chip, and, and a third interface between the third chip and the fourth chip are free of the molding member.

18. A semiconductor package comprising:
a package substrate comprising an external connection terminal connected to a lower pad formed on a lower surface thereof;
a first chip on an upper surface of the package substrate;
a second chip on the upper surface of the package substrate and spaced apart from the first chip in a horizontal direction;
a third chip disposed on the and the second chip; first chip
a film adhesive layer on a lower surface of the third chip;
a first fillet adhesive layer surrounding a side surface of the first chip, in contact with a portion of the lower surface of the third chip, and including a hardened liquid adhesive;
a second fillet adhesive layer between the second chip and the third chip and formed by hardening a liquid adhesive; and
a molding member on the package substrate and surrounding the first chip, the second chip, and the third chip,
wherein the film adhesive layer has a flat shape extending in the horizontal direction, a vertical level of an upper surface of the first chip is higher than a vertical level of an upper surface of the second chip, the third chip is attached to the first chip and the second chip, with a longitudinal direction of the third chip being substantially perpendicular to a height direction of each of the first chip and the second chip, an interface between the first chip and third chip is free of the first fillet adhesive layer, the second fillet adhesive layer protrudes from the upper surface of the second chip in the horizontal direction, both a first interface between the first chip and the third chip and a second interface between the second chip and the third chip are free of the molding member.

19. The semiconductor package of claim 18, wherein a height difference between the upper surface of the first chip and the upper surface of the second chip is within a range of 10 μm to 100 μm.

20. The semiconductor package of claim 18, further comprising a fourth chip between the first chip and the second chip and electrically connected to the package substrate.
